(19) United States
(12) Patent Application Publication
(10) Pub. No.: US 2024/0315049 A1
(43) Pub. Date: Sep. 19, 2024

(54) MAGNETIC MEMORY DEVICE, AND MANUFACTURING METHOD OF MAGNETIC MEMORY DEVICE

(71) Applicant: Kioxia Corporation, Tokyo (JP)

(72) Inventors: Takuya SHIMANO, Seoul (KR); Kenichi YOSHINO, Seongnam-si Gyeonggi-do (KR); Kazuya SAWADA, Seoul (KR); Naoki AKIYAMA, Seoul (KR); Hyungjun CHO, Seoul (KR)

(73) Assignee: Kioxia Corporation, Tokyo (JP)

(21) Appl. No.: 18/599,920

(22) Filed: Mar. 8, 2024

(30) Foreign Application Priority Data
Mar. 16, 2023 (JP) 2023-042091

(51) Int. Cl. H10B 61/00; H10N 50/01; H10N 50/20; H10N 50/85

(52) U.S. Cl. CPC H10B 61/10; H10N 50/01; H10N 50/20; H10N 50/85

(57) ABSTRACT

According to one embodiment, a magnetic memory device includes a switching element; a magnetoresistive effect element; and an electrode provided between the switching element and the magnetoresistive effect element, wherein the electrode includes a first sub-electrode in contact with the switching element, a second sub-electrode in contact with the magnetoresistive effect element, and a third sub-electrode provided between the first sub-electrode and the second sub-electrode, wherein the first sub-electrode and the second sub-electrode includes at least one of C and CN, and wherein the third sub-electrode includes at least one of a high melting point metal element and a compound of the high melting point metal element.

### CROSS-REFERENCE TO RELATED APPLICATIONS

This application is based upon and claims the benefit of priority from Japanese Patent Application No. 2023-042091, filed Mar. 16, 2023, the entire contents of which are incorporated herein by reference.

### FIELD

Embodiments described herein relate generally to a magnetic memory device, and a manufacturing method of magnetic memory device.

### BACKGROUND

A magnetic memory device (MRAM: Magnetoresistive Random Access Memory) including a magnetoresistive effect element as a storage element is known. The magnetoresistive effect element is coupled in series with the switching element and functions as a memory cell.

### BRIEF DESCRIPTION OF DRAWINGS

FIG. 1 is a block diagram for describing a configuration of a magnetic memory device according to an embodiment.

FIG. 2 is a circuit diagram for describing a configuration of a memory cell array of the magnetic memory device according to the embodiment.

FIG. 3 is a plan view for describing a configuration of a memory cell array of the magnetic memory device according to the embodiment.

FIG. 4 is a cross-sectional view taken along line IV-IV of FIG. 3, illustrating an example of a cross-sectional structure of a memory cell array of the magnetic memory device according to the embodiment.

FIG. 5 is a cross-sectional view for describing a configuration of a magnetoresistive effect element of the magnetic memory device according to the embodiment.

FIG. 6 is a flowchart for describing a first method of manufacturing a memory cell array in the magnetic memory device according to the embodiment.

FIG. 7 is a cross-sectional view for describing the first method of manufacturing the memory cell array in the magnetic memory device according to the embodiment.

FIG. 8 is a cross-sectional view for describing the first method of manufacturing the memory cell array in the magnetic memory device according to the embodiment.

FIG. 9 is a cross-sectional view for describing the first method of manufacturing the memory cell array in the magnetic memory device according to the embodiment.

FIG. 10 is a cross-sectional view for describing the first method of manufacturing the memory cell array in the magnetic memory device according to the embodiment.

FIG. 11 is a cross-sectional view for describing the first method of manufacturing the memory cell array in the magnetic memory device according to the embodiment.

FIG. 12 is a flowchart for describing a second method of manufacturing the memory cell array in the magnetic memory device according to the embodiment.

FIG. 13 is a cross-sectional view for describing the second method of manufacturing the memory cell array in the magnetic memory device according to the embodiment.

FIG. 14 is a cross-sectional view for describing the second method of manufacturing the memory cell array in the magnetic memory device according to the embodiment.

### DETAILED DESCRIPTION

In general, according to one embodiment, a magnetic memory device includes a switching element; a magnetoresistive effect element; and an electrode provided between the switching element and the magnetoresistive effect element, wherein the electrode includes a first sub-electrode in contact with the switching element, a second sub-electrode in contact with the magnetoresistive effect element, and a third sub-electrode provided between the first sub-electrode and the second sub-electrode, wherein the first sub-electrode and the second sub-electrode include at least one element or one compound selected from carbon (C) and carbon nitride (CN), and wherein the third sub-electrode includes at least one element or one compound selected from a high melting point metal element and a compound of the high melting point metal element.

Hereinafter, an embodiment will be described with reference to the drawings. In the following description, components having the same function and configuration are denoted by the same reference numerals. In addition, in a case where a plurality of components having a common reference sign is distinguished, the common reference sign is added with a suffix to be distinguished. Note that, in a case where a plurality of constituent elements does not need to be particularly distinguished, only common reference numerals are attached to the plurality of constituent elements, and no suffixes are attached thereto. Here, the suffix is not limited to a subscript or a superscript, and includes, for example, a lower case alphabet added to the end of the reference sign, an index meaning an array, and the like. In addition, in the present specification, the “A/B stacked film” indicates a stacked structure of a film including an element A and a film including an element B.

### 1. Embodiments

A magnetic memory device according to an embodiment will be described. The magnetic memory device according to the embodiment includes, for example, a perpendicular magnetization type magnetic memory device including an element having a magnetoresistive effect by a magnetic tunnel junction (MTJ) as a variable resistance element. In the following description, the variable resistance element is also referred to as a magnetoresistive effect element (MTJ element).

### 1.1 Configuration

First, a configuration of a magnetic memory device according to an embodiment will be described.

### 1.1.1 Configuration of Magnetic Memory Device

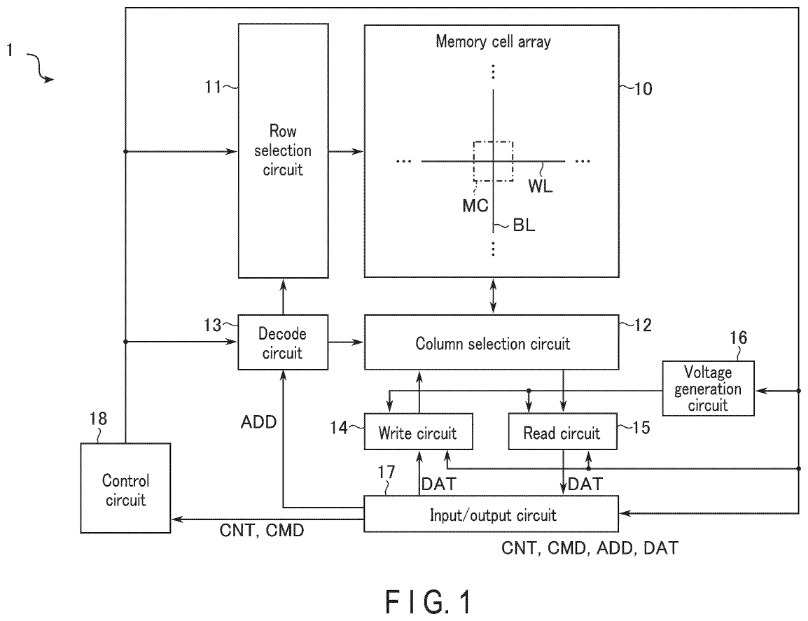

FIG. 1 is a block diagram illustrating a configuration of a magnetic memory device according to an embodiment. As illustrated in FIG. 1, a magnetic memory device 1 includes a memory cell array 10, a row selection circuit 11, a column selection circuit 12, a decode circuit 13, a write circuit 14, a read circuit 15, a voltage generation circuit 16, an input/output circuit 17, and a control circuit 18.

The memory cell array 10 includes a plurality of memory cells MC each associated with a set of rows and columns. The memory cells MC in the same row are coupled to the same word line WL. The memory cells MC in the same column are coupled to the same bit line BL.

The row selection circuit 11 is coupled to the memory cell array 10 via the word line WL. The decode result (row address) of the address ADD from the decode circuit 13 is supplied to the row selection circuit 11. The row selection circuit 11 sets the word line WL corresponding to the row based on the decoding result of the address ADD to the selected state. Hereinafter, the word line WL set to the selected state is referred to as a selected word line WL. The word lines WL other than the selected word line WL are referred to as unselected word lines WL.

The column selection circuit 12 is coupled to the memory cell array 10 via the bit line BL. The decoded result (column address) of the address ADD from the decode circuit 13 is supplied to the column selection circuit 12. The column selection circuit 12 sets the bit line BL corresponding to the column based on the decoding result of the address ADD to the selected state. Hereinafter, the bit line BL set to the selected state is referred to as a selected bit line BL. The bit lines BL other than the selected bit line BL are referred to as unselected bit lines BL.

The decode circuit 13 decodes the address ADD from the input/output circuit 17. The decode circuit 13 supplies a decoding result of the address ADD to the row selection circuit 11 and the column selection circuit 12. The address ADD includes a column address and a row address to be selected.

The write circuit 14 writes data to the memory cell MC. The write circuit 14 includes, for example, a write driver (not illustrated).

The read circuit 15 reads data from the memory cell MC. The read circuit 15 includes, for example, a sense amplifier (not illustrated).

The voltage generation circuit 16 generates voltages for various operations of the memory cell array 10 using a power supply voltage provided from an apparatus outside the magnetic memory device 1 (not illustrated). For example, the voltage generation circuit 16 generates various voltages necessary for the write operation to output the voltages to the write circuit 14. Furthermore, for example, the voltage generation circuit 16 generates various voltages required at the time of the read operation to output the voltages to the read circuit 15.

The input/output circuit 17 manages communication with the outside of the magnetic memory device 1. The input/output circuit 17 transfers the address ADD from the outside of the magnetic memory device 1 to the decode circuit 13. The input/output circuit 17 transfers the command CMD from the outside of the magnetic memory device 1 to the control circuit 18. The input/output circuit 17 transmits and receives various control signals CNT between the outside of the magnetic memory device 1 and the control circuit 18. The input/output circuit 17 transfers data DAT from the outside of the magnetic memory device 1 to the write circuit 14, and outputs the data DAT transferred from the read circuit 15 to the outside of the magnetic memory device 1.

The control circuit 18 controls operations of the row selection circuit 11, the column selection circuit 12, the decode circuit 13, the write circuit 14, the read circuit 15, the voltage generation circuit 16, and the input/output circuit 17 in the magnetic memory device 1 based on the control signal CNT and the command CMD.

### 1.1.2 Configuration of Memory Cell Array

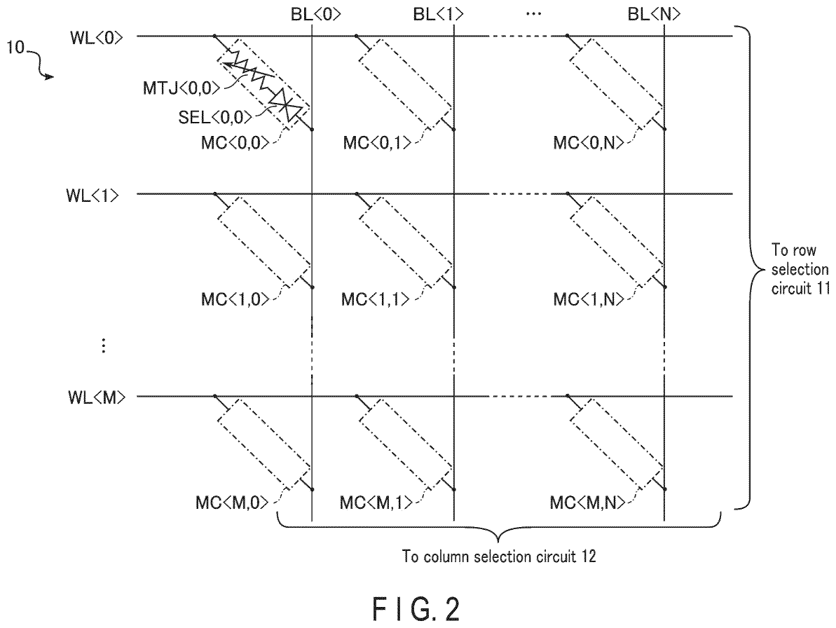

Next, a configuration of a memory cell array of the magnetic memory device 1 according to the embodiment will be described with reference to FIG. 2. FIG. 2 is a circuit diagram illustrating a configuration of a memory cell array of the magnetic memory device according to the embodiment. In FIG. 2, the word lines WL are shown classified by suffixes including indexes “< >”.

As shown in FIG. 2, the memory cells MC are disposed in a matrix in the memory cell array 10, and each of them is associated with a set of one of the plurality of bit lines BL (BL<0>, BL<1>, . . . , BL<N>) and one of the plurality of word lines WL (WL<0>, WL<1>, . . . , WL<M>) (M and N are natural numbers). That is, the memory cell MC<i, j> (0≤i≤M, 0≤j≤N) is coupled between the word line WL<i> and the bit line BL<j>.

The memory cell MC<i, j> includes a switching element SEL<i, j> and a magnetoresistive effect element MTJ<i, j> coupled in series.

The switching element SEL is a two-terminal switching element. The two-terminal switching element is different from a three-terminal switching element such as a transistor in that a third terminal is not included. In a case where the voltage applied between the two terminals is less than the threshold value voltage Vth (voltage applied between the two terminals<threshold value voltage Vth), the switching element SEL is in the high resistance state. The high resistance state is, for example, an “off” state that is an electrically non conductive state. In a case where the voltage applied between the two terminals is equal to or higher than the threshold value voltage Vth (voltage applied between the two terminals≥threshold value voltage Vth), the switching element SEL changes to the low resistance state. The low resistance state is, for example, an “on” state that is electrically conductive state. More specifically, for example, in a case where the voltage applied to the corresponding memory cell MC is less than the threshold value voltage Vth (voltage applied to the corresponding memory cell MC<threshold value voltage Vth), the switching element SEL cuts off the current as an insulator having a large resistance value. That is, it is turned off. In a case where the voltage applied to the corresponding memory cell MC is equal to or higher than the threshold value voltage Vth (voltage applied to the corresponding memory cell MC≥threshold value voltage Vth), the switching element SEL causes a current to flow as a conductor having a small resistance value. That is, it is turned on. The switching element SEL switches whether to flow or block the current according to the magnitude of the voltage applied to the corresponding memory cell MC regardless of the polarity of the voltage applied between the two terminals (regardless of the direction of the current flowing).

The magnetoresistive effect element MTJ can switch the resistance state between the low resistance state and the high resistance state by the current controlled by the switching element SEL. The magnetoresistive effect element MTJ can write data by a change in its resistance state, stores the written data in a nonvolatile manner, and functions as a readable storage element.

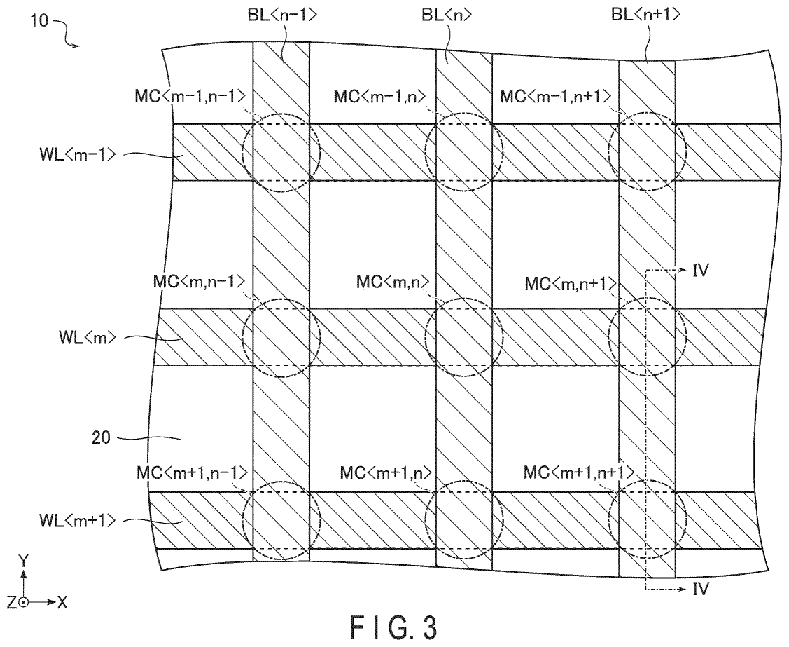

Next, the shape of the memory cell MC in the memory cell array 10 and the arrangement of the memory cell MC with respect to the bit line BL and the word line WL will be described with reference to FIG. 3. FIG. 3 illustrates an example of a plan view for describing the configuration of the memory cell array of the magnetic memory device according to the embodiment. FIG. 3 illustrates a plurality of memory cells MC provided between three word lines WL<m−1>, WL<m>, and WL<m+1> and three bit lines BL<n−1>, BL<n>, and BL<n+1> (1≤m≤M−1, 1≤n≤N−1) of the memory cell array 10. For convenience of description, the interlayer insulating film is omitted in FIG. 3.

As illustrated in FIG. 3, the memory cell array 10 is provided above a semiconductor substrate 20. In the following description, a plane parallel to the surface of the semiconductor substrate 20 is an XY plane, and a direction perpendicular to the XY plane is a Z direction. One of sets of two directions orthogonal to each other in the XY plane is defined as an X direction and a Y direction.

The plurality of memory cells MC is provided between the word line WL and the bit line BL. In the example of FIG. 3, a case where the word line WL is provided below the memory cell MC and the bit line BL is provided above the memory cell MC is shown, but the present invention is not limited thereto, and the vertical relationship between the word line WL and the bit line BL may be reversed.

Each of the plurality of memory cells MC has, for example, a circular shape along the XY cross section.

The plurality of word lines WL is disposed along the Y direction. Each of the plurality of word lines WL extends along the X direction. The plurality of bit lines BL is disposed along the X direction. Each of the plurality of bit lines BL extends along the Y direction. The distance between the two word lines WL and the distance between the two bit lines BL can be set to be substantially equal, for example. A memory cell MC is provided at a portion where one bit line BL and one word line WL intersect.

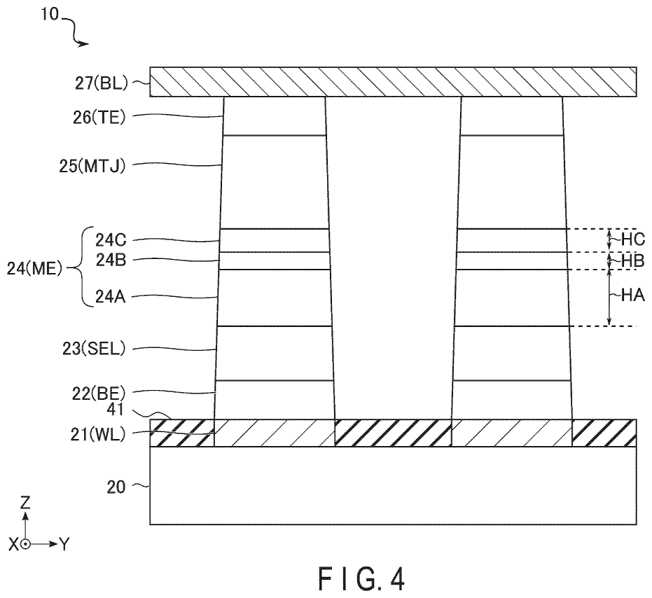

Next, a cross-sectional structure of the memory cell array 10 will be described with reference to FIG. 4. FIG. 4 is a cross-sectional view taken along line IV-IV of FIG. 3, illustrating an example of a cross-sectional structure of the memory cell array of the magnetic memory device according to the embodiment.

The memory cell array 10 is provided above the semiconductor substrate 20.

The memory cell array 10 includes a plurality of conductors 21, a plurality of electrodes 22, a plurality of elements 23, a plurality of electrodes 24, a plurality of elements 25, a plurality of electrodes 26, and a plurality of conductors 27.

For example, a plurality of conductors 21 is provided on the upper surface of the semiconductor substrate 20. The plurality of conductors 21 is disposed along the Y direction. Each of the plurality of conductors 21 extends along the X direction in a region (not illustrated). Each of the plurality of conductors 21 has conductivity and functions as the word line WL. An insulator 41 is provided between two adjacent conductors 21. As a result, each of the plurality of conductors 21 is insulated from each other. In FIG. 4, the case where the plurality of conductors 21 is provided on the semiconductor substrate 20 is described, but the present invention is not limited thereto. For example, the plurality of conductors 21 may be provided away from the semiconductor substrate 20 without being in contact with the semiconductor substrate 20.

The plurality of electrodes 22 is provided on the upper surface of each of the plurality of conductors 21. The plurality of electrodes 22 provided on the upper surface of the same conductor 21 is disposed in the X direction in a region (not illustrated). In FIG. 4, two electrodes 22 provided on two conductors 21 of the plurality of electrodes 22 is illustrated. Each of the plurality of electrodes 22 is used as the lower electrode BE.

One corresponding element 23 among the plurality of elements 23 is provided on the upper surface of each of the plurality of electrodes 22. Each of the plurality of elements 23 is used as the switching element SEL. Each of the plurality of elements 23 forms a switching layer, and Each of the plurality of elements 23 is also referred to as a switching layer 23. Hereinafter, it is denoted as the element 23.

One corresponding electrode 24 among the plurality of electrodes 24 is provided on the upper surface of each of the plurality of elements 23. Each of the plurality of electrodes 24 functions as an intermediate electrode ME. Details of the configuration of the electrode 24 will be described later.

One corresponding element 25 among the plurality of elements 25 is provided on the upper surface of each of the plurality of electrodes 24. Each of the plurality of elements 25 functions as a magnetoresistive effect element MTJ. Each of the plurality of elements 25 forms an MTJ layer, and Each of the plurality of elements 25 is also referred to as an MTJ layer 25. Hereinafter, it is denoted as the element 25. Details of the configuration of the element 25 will be described later.

One corresponding electrode 26 among the plurality of electrodes 26 is provided on the upper surface of each of the plurality of elements 25. Each of the plurality of electrodes 26 is used as an upper electrode TE.

One conductor 27 extending along the Y direction is provided so as to be in contact with the upper surface of each of the plurality of electrodes 26 disposed along the Y direction. The plurality of conductors 27 is disposed along the X direction in a region (not illustrated). Each of the plurality of conductors 27 extends along the Y direction. Each of the plurality of conductors 27 has conductivity and functions as the bit line BL.

### 1.1.3 Intermediate Electrode

Next, the configuration of the intermediate electrode ME of the magnetic memory device 1 according to the embodiment will be continuously described with reference to FIG. 4.

The plurality of electrodes 24 includes conductors 24A, 24B, and 24C.

The conductor 24A is provided on the upper surface of each of the plurality of elements 23. The conductor 24A includes, for example, at least one element or one compound selected from carbon (C) and carbon nitride (CN). The conductor 24A preferably has an amorphous structure. The height HA from the lower surface to the upper surface of the conductor 24A is, for example, from 2 nanometers (nm) to 20 nanometers (nm). When the height HA is within such a range, peeling of the conductor 24A from the upper surface of the element 23 is suppressed.

In the present specification, a portion “including” respective elements may include unintended impurities different from the element. The unintended impurities include, for example, an element included in a gas used in the manufacturing process of the magnetic memory device 1 and an element mixed into the portion from the periphery of the portion.

The conductor 24B is provided on the upper surface of the conductor 24A. The conductor 24B includes, for example, at least one element or one compound selected from a high melting point metal element and a compound of the high melting point metal element. In the present embodiment, the high melting point metal is, for example, a material having a melting point higher than that of iron (Fe) and cobalt (Co). The high melting point metal element and the compound of the high melting point metal element include, for example, titanium (Ti), tantalum (Ta), tungsten (W), titanium nitride (TiN), tantalum nitride (TaN), and tungsten nitride (WN). The conductor 24B has, for example, a crystal structure. The height HB from the lower surface to the upper surface of the conductor 24B is preferably, for example, from 0.1 nanometers (nm) to 3 nanometers (nm).

The conductor 24C is provided on the upper surface of the conductor 24B. As in the conductor 24A, the conductor 24C includes at least one element or one compound selected from carbon (C) and carbon nitride (CN), for example. The conductor 24C preferably has an amorphous structure. The height HC from the lower surface to the upper surface of the conductor 24C is preferably, for example, from 0.1 nanometers (nm) to 3 nanometers (nm). The surface roughness (roughness and flatness) of the upper surface of the conductor 24C has, for example, a parameter Ra of 0.6 nanometers (nm) or less.

In the configuration of the electrode 24 as described above, the lower surface of the conductor 24B is located, for example, at a height equal to or higher than the position of the center of the electrode 24 in the Z direction. As a result, the height HA of the conductor 24A is, for example, a height equal to or more than half the height (HA+HB+HC) from the lower surface of the electrode 24 to the upper surface of the electrode 24 (HA≥(HA+HB+HC)/2).

### 1.1.4 Magnetoresistive Effect Element

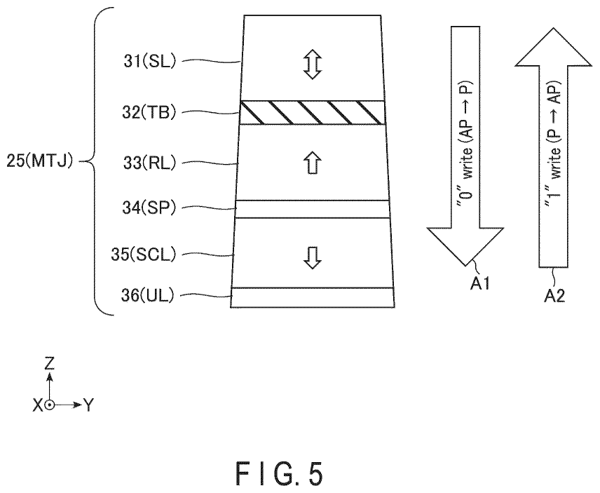

Next, the configuration of the magnetoresistive effect element MTJ of the magnetic memory device 1 according to the embodiment will be described with reference to FIG. 5. FIG. 5 is a cross-sectional view illustrating a configuration of a magnetoresistive effect element of the magnetic memory device according to the embodiment.

The element 25 used as the magnetoresistive effect element MTJ includes a ferromagnetic material 31, a nonmagnetic material 32, a ferromagnetic material 33, a nonmagnetic material 34, a ferromagnetic material 35, and a nonmagnetic material 36.

The ferromagnetic material 31 is a conductive film having ferromagnetism. The ferromagnetic material 31 has an easy magnetization axis direction in a direction perpendicular to the film surface (Z direction). The ferromagnetic material 31 includes iron (Fe). The ferromagnetic material 31 may further include at least one element of cobalt (Co) and nickel (Ni). In addition, the ferromagnetic material 31 may further include boron (B). More specifically, for example, the ferromagnetic material 31 includes cobalt iron boron (CoFeB), iron boride (FeB), or cobalt boride (CoB). The ferromagnetic material 31 is used as a storage layer SL.

The nonmagnetic material 32 is provided on the lower surface of the ferromagnetic material 31. The nonmagnetic material 32 is an insulating film having nonmagnetism. The nonmagnetic material 32 is used as a tunnel barrier layer TB. The nonmagnetic material 32 is provided between the ferromagnetic material 31 and the ferromagnetic material 33, and forms a magnetic tunnel junction together with the ferromagnetic material 31 and the ferromagnetic material 33. In a case where an initial amorphous layer such as cobalt iron boron (CoFeB) is used for the interface layer between the ferromagnetic material 31 and the ferromagnetic material 33, the nonmagnetic material 32 functions as a seed material to be a nucleus for growing a crystalline film from the interface with the ferromagnetic material 31 in the crystallization process of the ferromagnetic material 31. Similarly, in a case where cobalt iron boron (CoFeB) is used as the interface layer of the ferromagnetic material 33, the nonmagnetic material 32 also functions as a seed material for the ferromagnetic material 33. Here, the initial amorphous layer is a layer that is in an amorphous state immediately after film formation and crystallizes after annealing treatment. The nonmagnetic material 32 has a tetragonal or cubic structure in which a film surface is oriented in a (001) plane. Examples of the oxide used for the nonmagnetic material 32 include magnesium oxide (MgO). Magnesium oxide (MgO) has a NaCl structure. In a case where magnesium oxide (MgO) is used for the nonmagnetic material 32, a (001) interface of magnesium oxide (MgO) and a (001) interface of cobalt iron boron (CoFeB) are matched with each other. For this reason, cobalt iron boron (CoFeB) is crystal-grown by annealing treatment to form a (001) oriented body-centered cubic structure.

The ferromagnetic material 33 is provided on the lower surface of the nonmagnetic material 32. The ferromagnetic material 33 is a conductive film having ferromagnetism. The ferromagnetic material 33 is used as a reference layer RL. The ferromagnetic material 33 has an easy magnetization axis direction in a direction perpendicular to the film surface (Z direction). The magnetization direction of the ferromagnetic material 33 is fixed. In the example of FIG. 5, the magnetization direction of the ferromagnetic material 33 is a direction from the ferromagnetic material 33 toward the ferromagnetic material 31. Note that “the magnetization direction is fixed” means that the magnetization direction does not change by a torque of a magnitude that can reverse the magnetization direction of the ferromagnetic material 31. Usually, an interface layer is used for the ferromagnetic material 33. As the interface layer of the ferromagnetic material 33, an initial amorphous layer such as cobalt iron boron (CoFeB) is used. Further, an auxiliary ferromagnetic layer is provided so as to be in contact with a surface of the cobalt iron boron (CoFeB) layer, the surface being opposite to a surface in contact with the magnesium oxide (MgO) layer. The auxiliary ferromagnetic layer includes, for example, at least one alloy film selected from cobalt platinum (CoPt), cobalt nickel (CoNi), and cobalt palladium (CoPd). The auxiliary ferromagnetic layer is a stacked film such as a stacked film including Co/Pt or a stacked film including Co/Pd. The cobalt-iron boron (CoFeB) layer serving as the initial amorphous layer is used by being stacked with the stacked film including CoPt, CoPd, and Co/Pt, the stacked film including Co/Pd, or the like. In this case, in the interface layer of the ferromagnetic material 33, for example, the above-described CoFeB layer is formed so that (001)-oriented MgO is provided on the nonmagnetic material 32 side than the other layers.

The nonmagnetic material 34 is provided on the lower surface of the ferromagnetic material 33. The nonmagnetic material 34 is a conductive film having nonmagnetism. The nonmagnetic material 34 is used as a spacer layer SP. The nonmagnetic material 34 includes, for example, an element selected from ruthenium (Ru), osmium (Os), rhodium (Rh), iridium (Ir), vanadium (V), and chromium (Cr), or an alloy thereof. For example, the film thickness of the nonmagnetic material 34 is 2 nanometers (nm) or less.

The ferromagnetic material 35 is provided on the lower surface of the nonmagnetic material 34. The ferromagnetic material 35 is a conductive film having ferromagnetism. The ferromagnetic material 35 is used as a shift cancel layer SCL. The ferromagnetic material 35 has an easy magnetization axis direction in a direction perpendicular to the film surface (Z direction). The magnetization direction of the ferromagnetic material 35 is fixed. In the example of FIG. 5, the magnetization direction of the ferromagnetic material 35 is a direction from the ferromagnetic material 33 toward the ferromagnetic material 35. The ferromagnetic material 35 includes, for example, at least one alloy layer selected from cobalt platinum (CoPt), cobalt nickel (CoNi), and cobalt palladium (CoPd). In addition, the ferromagnetic material 35 may be a stacked film such as a stacked film including Co/Pt and a stacked film including Co/Pd.

The ferromagnetic material 33 and the ferromagnetic material 35 are antiferromagnetically coupled by the nonmagnetic material 34. That is, the ferromagnetic material 33 and the ferromagnetic material 35 are coupled so as to have magnetization directions antiparallel to each other. Such a coupling structure of the ferromagnetic material 33, the nonmagnetic material 34, and the ferromagnetic material 35 is referred to as a synthetic anti-ferromagnetic (SAF) structure. With the SAF structure, the ferromagnetic material 35 can offset the influence of the leakage magnetic field of the ferromagnetic material 33 on the change in the magnetization direction of the ferromagnetic material 31. As a result, the ferromagnetic material 35 can reduce the substantial leakage magnetic field of the ferromagnetic material 33.

The nonmagnetic material 36 is provided on the lower surface of the ferromagnetic material 35. The nonmagnetic material 36 is a conductive film having nonmagnetism. The nonmagnetic material 36 is used as an under layer (UL). The nonmagnet 38 includes at least one element selected from, for example, zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The magnetoresistive effect element MTJ can take either a low resistance state or a high resistance state depending on whether the relative relationship in the magnetization direction between the storage layer SL and the reference layer RL is parallel or antiparallel. In the embodiment, the magnetization direction of the storage layer SL with respect to the magnetization direction of the reference layer RL is controlled by applying a write current to such a magnetoresistive effect element MTJ. Specifically, a write method using spin transfer torque generated by applying a current to the magnetoresistive effect element MTJ is employed.

When a write current Ic0 having a certain magnitude is applied to the magnetoresistive effect element MTJ in the direction from the storage layer SL toward the reference layer RL, that is, in the direction of the arrow A1 in FIG. 5, the relative relationship in the magnetization direction between the storage layer SL and the reference layer RL is parallel. In this parallel state, the resistance value of the magnetoresistive effect element MTJ is the lowest, and the magnetoresistive effect element MTJ is set to the low resistance state. This low resistance state is referred to as a “parallel (P) state” and is defined as, for example, a state of data “0”.

In addition, when a write current Ic1 larger than a write current Ic0 is applied to the magnetoresistive effect element MTJ in the direction from the reference layer RL toward the storage layer SL, that is, in the direction of the arrow A2 in FIG. 5, the relative relationship in the magnetization direction between the storage layer SL and the reference layer RL is antiparallel. In the antiparallel state, the resistance value of the magnetoresistive effect element MTJ is the highest, and the magnetoresistive effect element MTJ is set to the high resistance state. This high resistance state is referred to as an “antiparallel (AP) state” and is defined as, for example, a state of data “1”.

Note that the manner of defining the data “1” and the data “0” is not limited to the above-described example. For example, the P state may be defined as data “1”, and the AP state may be defined as data “0”.

### 1.2 Method of Manufacturing Memory Cell Array

Next, a method of manufacturing the memory cell array 10 of the magnetic memory device 1 according to the embodiment will be described. Hereinafter, a first manufacturing method and a second manufacturing method will be described for the method of manufacturing the memory cell array 10 of the magnetic memory device 1 according to the embodiment.

### 1.2.1 First Manufacturing Method

A first method of manufacturing the memory cell array 10 in the magnetic memory device 1 according to the embodiment will be described.

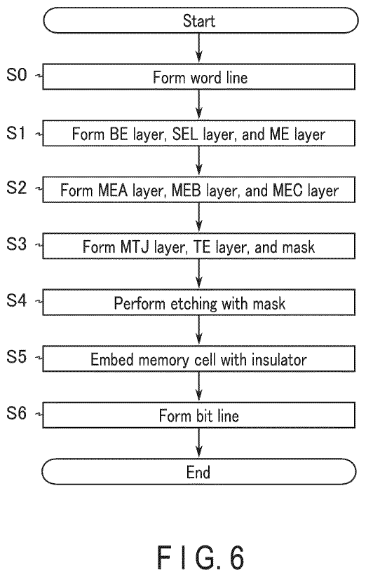

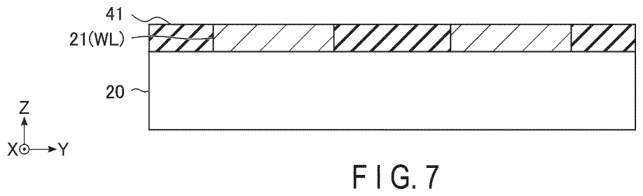

FIG. 6 is a flowchart for describing the first method of manufacturing the memory cell array in the magnetic memory device according to the embodiment. FIGS. 7 to 11 are cross-sectional views for describing the first method of manufacturing the memory cell array in the magnetic memory device according to the embodiment. FIGS. 7 to 11 are cross sections corresponding to the cross section of FIG. 4.

In S0 of FIG. 6, as illustrated in FIG. 7, a plurality of conductors 21 is provided as a plurality of word lines WL on the upper surface of the semiconductor substrate 20 as a wafer WF. Specifically, first, a conductor layer is provided on the upper surface of the semiconductor substrate 20, and then a mask whose portion excluding a region corresponding to the word line WL is opened by photolithography or the like is formed. Then, the conductor layer is divided by anisotropic etching using the formed mask to form the plurality of conductors 21, and a hole reaching the semiconductor substrate 20 is formed. The anisotropic etching in this process is, for example, reactive ion etching (RIE). Thereafter, the insulator 41 is provided in the formed hole.

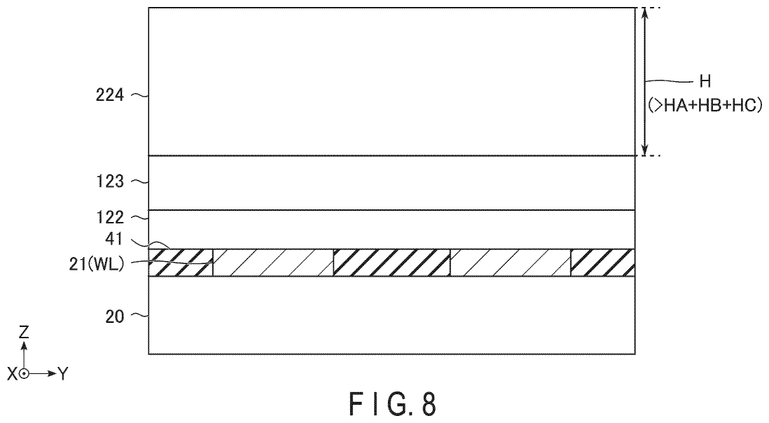

Next, in S1 of FIG. 6, as shown in FIG. 8, an electrode layer 122, a selector layer 123, and a conductor layer 224 are formed in this order on the upper surfaces of the plurality of conductors 21 and the insulator 41. The conductor layer 224 is formed by depositing at least one element or one compound selected from carbon (C) and carbon nitride (CN) on the upper surface of the selector layer 123. In FIG. 6, the electrode layer 122, the selector layer 123, and the conductor layer 224 are referred to as a BE layer, a SEL layer, and an ME layer, respectively. The height H of the conductor layer 224 along the Z direction is thicker than the height (HA+HB+HC) of the plurality of electrodes 24 of the magnetoresistive effect element MTJ to be manufactured (H>HA+HB+HC).

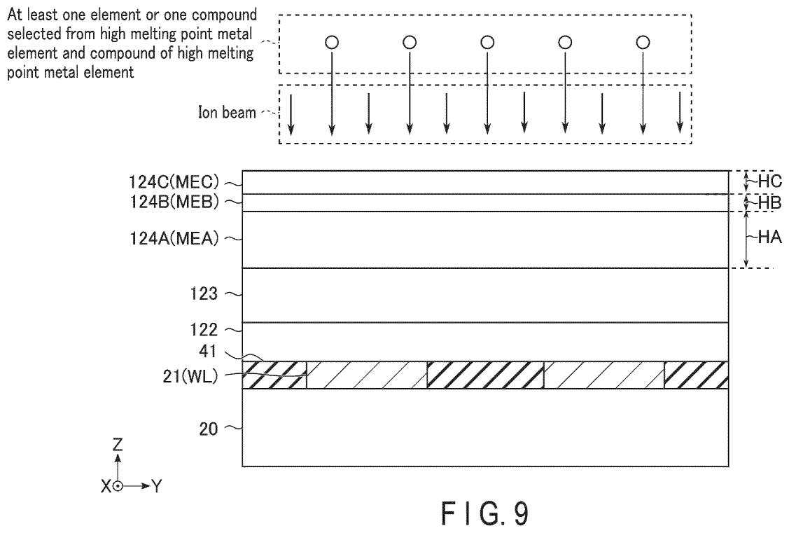

Then, in S2 of FIG. 6, as shown in FIG. 9, electrode layers 124A, 124B, and 124C are formed. The electrode layers 124A, 124B, and 124C correspond to the conductors 24A, 24B, and 24C described in FIG. 4, respectively. The electrode layers 124A and 124C include at least one element or one compound selected from carbon (C) and carbon nitride (CN). The electrode layer 124B includes at least one element or one compound selected from a high melting point metal and a compound of a high melting point metal element. In FIG. 6, the electrode layers 124A, 124B, and 124C are described as a MEA layer, a MEB layer, and a MEC layer, respectively.

Specifically, the conductor layer 224 formed in S1 is etched by ion beam etching. At the time of the ion beam etching, for example, in an ion beam generator (not shown), at least one element or one compound selected from a high melting point metal and a compound of a high melting point metal element is implanted into the conductor layer 224 together with the etching of the conductor layer 224. As a result, the electrode layer 124B including at least one element or one compound selected from a high melting point metal and a compound of a high melting point metal element is formed in the etched conductor layer 224. Of the etched conductor layer 224, a portion below the electrode layer 124B and a portion above the electrode layer 124B are formed as the electrode layers 124A and 124C, respectively. The high melting point metal and the compound of the high melting point metal element to be implanted into the conductor layer 224 can be generated in an ion beam generator (not illustrated), for example, at the time of ion beam etching.

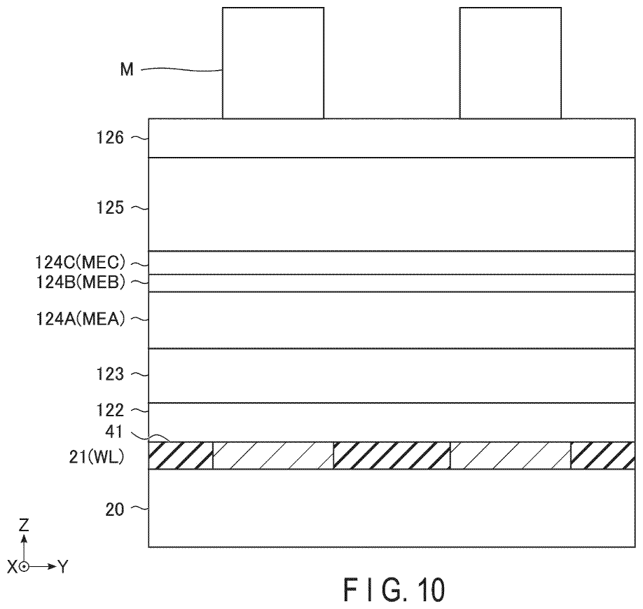

Then, in S3 of FIG. 6, as illustrated in FIG. 10, a magnetoresistive effect element layer 125, an electrode layer 126, and the plurality of masks M are formed in this order on the upper surface of the electrode layer 124C. In FIG. 6, the magnetoresistive effect element layer 125 and the electrode layer 126 are referred to as an MTJ layer and a TE layer, respectively. The magnetoresistive effect element layer 125 is a stacked body in which each layer included in the magnetoresistive effect element MTJ described in FIG. 5 is formed in a flat plate shape in this stack order. In addition, the plurality of masks M whose portion excluding regions corresponding to the lower electrode BE, the switching element SEL, the intermediate electrode ME, the magnetoresistive effect element MTJ, and the upper electrode TE to be manufactured of the electrode layer 122, the selector layer 123, the electrode layers 124A to 124C, and the magnetoresistive effect element layer 125 is opened by photolithography or the like is formed. The plurality of masks M includes, for example, titanium nitride (TiN), and protects portions functioning as the switching element SEL, the intermediate electrode ME, and the magnetoresistive effect element MTJ in ion beam etching described later. The plurality of masks M is provided, for example, as a plurality of columnar structures disposed in a matrix on the upper surface of the magnetoresistive effect element layer 125, and each of the plurality of columnar structures protects a region corresponding to a memory cell MC.

Next, in S4 of FIG. 6, the electrode layers 122, 124A to 124C, and 126, the selector layer 123, and the magnetoresistive effect element layer 125 are etched by ion beam etching. As a result, portions of the electrode layers 122, 124A to 124C, and 126, the selector layer 123, and the magnetoresistive effect element layer 125 that are not protected by the plurality of masks M are removed, and the conductor 21 and the insulator 41 located below the portions are exposed. By such ion beam etching, a plurality of stacked structures each including the electrodes 22, 24, and 26 and the elements 23 and 25 are formed from the electrode layers 122, 124A to 124C, and 126, the selector layer 123, and the magnetoresistive effect element layer 125.

Then, in S5 of FIG. 6, after the plurality of masks M is removed, a space in which the electrode layers 122, 124A to 124C, and 126, the selector layer 123, and the magnetoresistive effect element layer 125 are etched by the ion beam is embedded by the insulator 42.

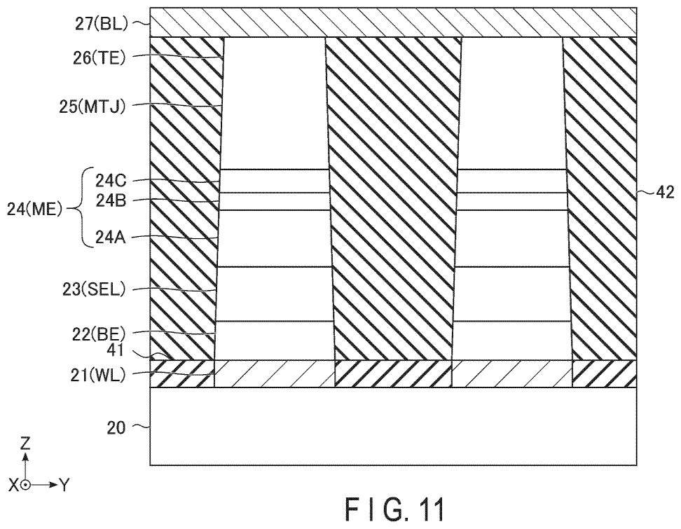

Then, in S6 of FIG. 6, as illustrated in FIG. 11, a plurality of conductors 27 disposed along the Y direction is provided on the upper surfaces of the element 25 and the insulator 42. Specifically, first, a conductor layer is provided on the upper surfaces of the element 25 and the insulator 42, and then, a mask whose portion excluding a region corresponding to the bit line BL is opened by photolithography or the like is formed. Then, the conductor layer is divided by anisotropic etching using the formed mask to form the plurality of conductors 27, and a hole reaching the insulator 42 is formed. The anisotropic etching in this process is, for example, RIE. Thereafter, an insulator (not illustrated) is provided in the formed hole.

As described above, a configuration corresponding to the memory cell array 10 is formed on the wafer WF by the first manufacturing method. Then, the wafer WF is diced in units of chips to form the magnetic memory device 1.

### 1.2.2 Second Manufacturing Method

Next, a second manufacturing method of the memory cell array 10 in the magnetic memory device 1 according to the embodiment will be mainly described with respect to points different from those of the first manufacturing method.

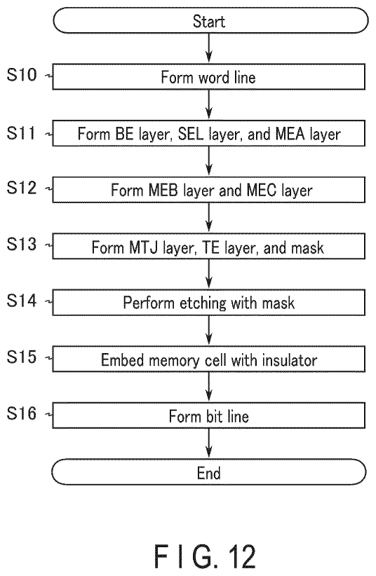

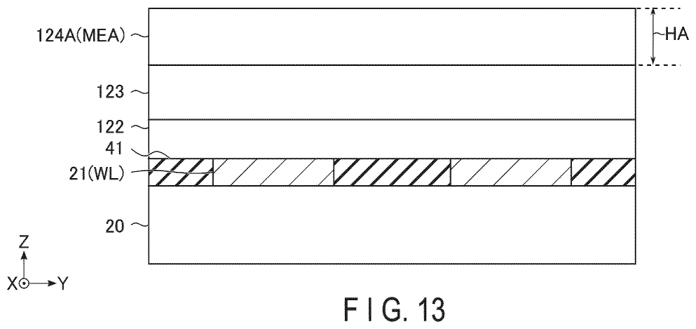

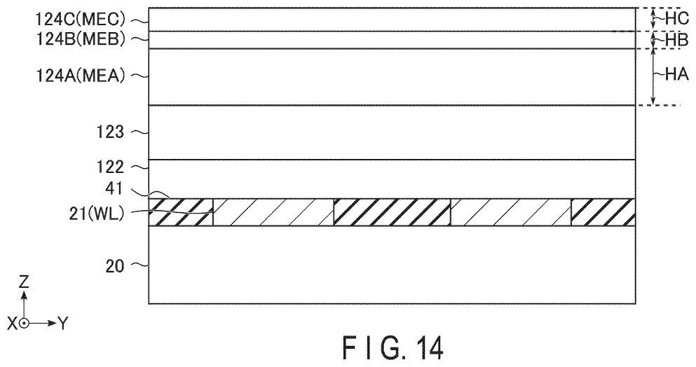

FIG. 12 is a flowchart for describing the second method of manufacturing the memory cell array in the magnetic memory device according to the embodiment. FIGS. 13 and 14 are cross-sectional views for describing the second method of manufacturing the memory cell array in the magnetic memory device according to the embodiment. FIGS. 13 and 14 are cross sections corresponding to the cross section of FIG. 4.

S10 in FIG. 12 is a process equivalent to S0 in the first manufacturing method.

Next, in S11 of FIG. 12, as shown in FIG. 13, the electrode layer 122, the selector layer 123, and the electrode layer 124A are formed in this order on the upper surfaces of the conductor 21 and the insulator 41.

With respect to the formation of the electrode layer 124A, specifically, for example, a conductor layer thicker than the conductor 24A of FIG. 4 is formed on the upper surface of the selector layer 123. The conductor layer is formed by depositing at least one element or one compound selected from carbon (C) and carbon nitride (CN) on the upper surface of the selector layer 123. Then, the upper end portion of the conductor layer is removed by, for example, chemical mechanical polishing (CMP). Thus, the electrode layer 124A is formed. The height from the upper surface to the lower surface of the electrode layer 124A is equivalent to the height HA of the conductor 24A.

In the process of forming the electrode layer 124A, CMP may not be performed. In this case, at least one element or one compound selected from carbon (C) and carbon nitride (CN) is deposited on the upper surface of the selector layer 123 by the height HA without performing CMP. Thus, the electrode layer 124A is formed.

Then, in S12 of FIG. 12, as shown in FIG. 14, the electrode layers 124B and 124C are formed in this order.

Specifically, at least one element or one compound selected from a high melting point metal and a compound of the high melting point metal element is deposited on the upper surface of the electrode layer 124A. Thus, the electrode layer 124B is formed. In the second manufacturing method, the electrode layer 124B is formed using, for example, physical vapor deposition (PVD), self-ionized sputtering (SIP), atomic layer deposition (ALD), chemical vapor deposition (CVD), or the like. Then, the electrode layer 124C is formed on the upper surface of the electrode layer 124B. The electrode layer 124C is formed by depositing at least one element or one compound selected from carbon (C) and carbon nitride (CN) on the upper surface of the electrode layer 124B.

The height from the upper surface to the lower surface of the electrode layer 124B and the height from the upper surface to the lower surface of the electrode layer 124C are equal to the height HB of the conductor 24B and the height HC of the conductor 24C, respectively.

Then, S13 to S16 in FIG. 12 are executed. S13 to S16 can be equivalent to S3 to S6 of the first manufacturing method.

As described above, the configuration corresponding to the memory cell array 10 is formed on the wafer WF by the second manufacturing method. As in the first manufacturing method, the wafer WF is diced in units of chips to form the magnetic memory device 1.

### 1.3 Effects According to Present Embodiment

According to the embodiment, the properties of the magnetoresistive effect element MTJ can be improved. Effects of the embodiment will be described below.

In the memory cell MC of the magnetic memory device 1 according to the embodiment, the electrode 24 functioning as the intermediate electrode ME is provided between the element 23 functioning as the switching element SEL and the element 25 functioning as the magnetoresistive effect element MTJ. The electrode 24 includes the conductors 24A, 24B, and 24C. The conductor 24A is in contact with the element 23. The conductor 24C is in contact with the element 25. The conductor 24B is provided between the conductors 24A and 24C. The conductors 24A and 24C include at least one element or one compound selected from carbon (C) and carbon nitride (CN). The conductor 24B includes at least one element or one compound selected from a high melting point metal element and a compound of the high melting point metal element. By providing such a conductor 24B between the conductors 24A and 24C, deterioration of the properties of the element 25 due to the influence of the electrode 24 is suppressed. As a result, the properties of the magnetoresistive effect element MTJ can be improved.

To supplement, in a case where the intermediate electrode does not include a conductor layer including at least one element or one compound selected from a high melting point metal element and a compound of the high melting point metal element, the surface roughness of the upper surface of the intermediate electrode in contact with the magnetoresistive effect element may be deteriorated, for example, due to the influence of the upper surface of the switching element on which the intermediate electrode is deposited. That is, in a case where the upper surface of the switching element is rough, the surface roughness of the upper surface of the intermediate electrode may deteriorate due to the influence of the upper surface of the switching element. In such a case, for example, carbon or carbon nitride included in the intermediate electrode may be easily mixed into the magnetoresistive effect element. This may deteriorate the properties of the magnetoresistive effect element.

According to the embodiment, the conductor 24B provided between the conductors 24A and 24C includes a high melting point metal element or a high melting point metal element. The conductor 24B has, for example, a crystal structure. As a result, even in a case where the upper surface of the element 23 is rough, deterioration of the surface roughness of the upper surface of the electrode 24 can be suppressed by including the conductor 24B having the above-described configuration in the electrode 24.

In addition, according to the embodiment, the conductor 24C having an amorphous structure is included between the magnetoresistive effect element MTJ and the conductor 24B. This suppresses the influence of the crystal structure of the conductor 24B on the structure of the magnetoresistive effect element MTJ. Specifically, the influence on the structure of the nonmagnetic material 36 functioning as the under layer UL in the magnetoresistive effect element MTJ is suppressed. This also makes it possible to improve the properties of the magnetoresistive effect element MTJ.

In addition, the electrode layer 124A is formed using CMP in S12 of the second manufacturing method, so that it is also possible to suppress deterioration of the surface roughness of the upper surface of the electrode layer 124A. This makes it possible to more effectively suppress deterioration of the surface roughness of the upper surface of the electrode 24.

### 2. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a switching element;
a magnetoresistive effect element; and
an electrode provided between the switching element and the magnetoresistive effect element, wherein
the electrode includes
a first sub-electrode in contact with the switching element,
a second sub-electrode in contact with the magnetoresistive effect element, and
a third sub-electrode provided between the first sub-electrode and the second sub-electrode, wherein
the first sub-electrode and the second sub-electrode include at least one element or one compound selected from carbon (C) and carbon nitride (CN), and wherein
the third sub-electrode includes at least one element or one compound selected from a high melting point metal element and a compound of the high melting point metal element.

2. The device of claim 1, wherein
the high melting point metal element and the compound of the high melting point metal element include titanium (Ti), tantalum (Ta), tungsten (W), titanium nitride (TiN), tantalum nitride (TaN), and tungsten nitride (WN).

3. The device of claim 1, wherein
each of the first sub-electrode and the second sub-electrode has an amorphous structure.

4. The device of claim 1, wherein
a height from a lower surface to an upper surface of the first sub-electrode is half or more of a height from a lower surface to an upper surface of the electrode.

5. The device of claim 1, wherein
a height from an upper surface to a lower surface of the first sub-electrode is from 2 nanometers (nm) to 20 nanometers (nm).

6. The device of claim 1, wherein
a height from an upper surface to a lower surface of the second sub-electrode is from 0.1 nanometers (nm) to 3 nanometers (nm).

7. The device of claim 1, wherein
a height from an upper surface to a lower surface of the third sub-electrode is from 0.1 nanometers (nm) to 3 nanometers (nm).

8. The device of claim 1, wherein
the magnetoresistive effect element is provided opposite to a substrate with respect to the switching element.

9. The device of claim 1, wherein
the magnetoresistive effect element includes
a first ferromagnetic layer,
a second ferromagnetic layer,
a third ferromagnetic layer provided opposite to the first ferromagnetic layer with respect to the second ferromagnetic layer,
a first nonmagnetic layer provided between the first ferromagnetic layer and the second ferromagnetic layer, and
a second nonmagnetic layer provided between the second ferromagnetic layer and the third ferromagnetic layer, and wherein
the first nonmagnetic layer includes an oxide of magnesium (Mg).

10. The device of claim 9, wherein
the second nonmagnetic layer includes at least one element selected from ruthenium (Ru), osmium (Os), rhodium (Rh), iridium (Ir), vanadium (V), and chromium (Cr).

11. The device of claim 9, wherein
the third ferromagnetic layer is provided between a substrate and the second ferromagnetic layer.

12. The device of claim 9, wherein
the second ferromagnetic layer and the third ferromagnetic layer are antiferromagnetically coupled.

13. The device of claim 1, wherein
the switching element is a two-terminal switching element.

14. A method of manufacturing a magnetic memory device, the method comprising:
forming an electrode layer including a first sub-electrode layer, a second sub-electrode layer, and a third sub-electrode layer in this order upward on an upper surface of a selector layer; and
forming a magnetoresistive effect element layer on an upper surface of the electrode layer, wherein
the forming the electrode layer includes
forming a conductor layer by depositing at least one element or one compound selected from carbon (C) and carbon nitride (CN) on an upper surface of the selector layer, and
forming the first sub-electrode layer and the third sub-electrode layer including at least one element or one compound selected from carbon (C) and carbon nitride (CN) and the second sub-electrode layer including at least one element or one compound selected from a high melting point metal element and a compound of the high melting point metal element by implanting at least one element or one compound selected from a high melting point metal and a compound of a high melting point metal element into the conductor layer while removing an upper end portion of the conductor layer by using ion beam etching.

15. A method of manufacturing a magnetic memory device comprising:
forming an electrode layer including a first sub-electrode layer, a second sub-electrode layer, and a third sub-electrode layer in this order upward on an upper surface of a selector layer; and
forming a magnetoresistive effect element layer on an upper surface of the electrode layer, wherein
the forming the electrode layer includes
forming a first sub-electrode layer by depositing at least one element or one compound selected from carbon (C) and carbon nitride (CN) on an upper surface of the selector layer,
forming a second sub-electrode layer by depositing at least one element or one compound selected from a high melting point metal and a compound of a high melting point metal element on an upper surface of the first sub-electrode layer, and
forming a third sub-electrode layer by depositing at least one element or one compound selected from carbon (C) and carbon nitride (CN) on an upper surface of the second sub-electrode layer.

16. The method of claim 15, wherein
the forming the first sub-electrode layer includes
forming a conductor layer by depositing at least one element or one compound selected from carbon (C) and carbon nitride (CN) on an upper surface of the selector layer, and
removing an upper end portion of the conductor layer using chemical mechanical polishing (CMP).
